(19) United States
(12) Patent Application Publication
(10) Pub. No.: US 2024/0258132 A1
(43) Pub. Date: Aug. 1, 2024

(54) PASSIVATION METHOD AND HEAT TREATMENT APPARATUS

(71) Applicant: SCREEN Holdings Co., Ltd., Kyoto (JP)

(72) Inventors: Oma NAKAJIMA, Kyoto-shi (JP); Mao OMORI, Kyoto-shi (JP)

(21) Appl. No.: 18/529,482

(22) Filed: Dec. 5, 2023

(30) Foreign Application Priority Data
Jan. 30, 2023 (JP) 2023-011759

(51) Int. Cl. H01L 21/67

(52) U.S. Cl. CPC H01L 21/67115; H01L 21/67017

(57) ABSTRACT

A chamber in a heat treatment apparatus is made of stainless steel. After pressure in the chamber is reduced, ozone is introduced into the chamber, and is sealed in the chamber by stopping the supply and exhaust of gas to and from the chamber. The ozone is kept sealed in the chamber for a waiting time period that is not greater than the half-life of ozone. The ozone having an extremely strong oxidizing power acts on an inner surface of the chamber made of stainless steel, whereby an inert passive film is formed on the inner surface. This inert passive film suppresses the precipitation of manganese from the chamber made of stainless steel. This prevents metal contamination of a semiconductor wafer from the chamber even when the semiconductor wafer is subjected to heating treatment in the chamber.

### BACKGROUND OF THE INVENTION

### Field of the Invention

The present invention relates to a heat treatment apparatus which irradiates a substrate with light to heat the substrate, and to a passivation method which forms a passive film on an inner surface of a chamber of the heat treatment apparatus. Examples of the substrate to be treated by the heat treatment apparatus include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

U.S. patent Application Publication No. 2021/0051771 discloses a heat treatment apparatus in which a semiconductor wafer received in a chamber is preheated by irradiation with light from halogen lamps, and thereafter a surface of the semiconductor wafer is irradiated with flashes of light from flash lamps. It is also disclosed in U.S. patent Application Publication No. 2021/0051771 that side walls of the chamber of the heat treatment apparatus are made of stainless steel.

Stainless steel is an alloy steel containing at least a certain amount of chromium (Cr) and is preferred as a material for the chamber of the heat treatment apparatus because of its excellent resistance to corrosion and heat. However, there have been cases in which manganese (Mn) contained in the stainless steel precipitates on an inner wall surface of the chamber made of stainless steel. If the precipitates adhere to a semiconductor wafer to be treated, there has been apprehension that the precipitates cause metal contamination.

The excellent corrosion resistance of stainless steel is due to the formation of a native oxide film of chromium as a passive film on the surface. This passive film also suppresses manganese precipitation. However, the passive film is damaged in some cases at joints and welds in the chamber. Metal contamination has resulted from such damaged locations in some cases.

### SUMMARY

The present invention is intended for a method of passivation for forming a passive film on an inner surface of a chamber of a heat treatment apparatus for heat-treating a substrate.

According to one aspect of the present invention, the method comprises the steps of: (a) introducing an oxidizing gas into a chamber containing stainless steel; and (b) forming a passive film on an inner surface of the chamber by means of the oxidizing gas.

The passive film suppresses the precipitation of manganese from the inner surface of the chamber to prevent metal contamination of a substrate from the chamber.

Preferably, the method further comprises the step of (c) stopping gas supply into and gas exhaust from the chamber to seal the oxidizing gas in the chamber for a predetermined waiting time period after introducing the oxidizing gas into the chamber.

This reduces the consumption of the oxidizing gas.

Preferably, a heat source heats the oxidizing gas sealed in the chamber during the execution of the step (c).

This shortens the processing time for the formation of the passive film.

Preferably, when an abnormality is detected during the execution of the step (c), nitrogen gas is supplied into the chamber to discharge the oxidizing gas after pressure in the chamber is reduced.

This ensures safety in the event of abnormalities.

The present invention is also intended for a heat treatment apparatus for heating a substrate by irradiating the substrate with light.

According to one aspect of the present invention, the heat treatment apparatus comprises: a chamber containing stainless steel; a gas supply part for supplying an oxidizing gas into the chamber; an exhaust part for exhausting gas from the chamber; and a light irradiation part for irradiating the interior of the chamber with light, wherein a passive film is formed on an inner surface of the chamber by means of the oxidizing gas supplied by the gas supply part.

The passive film suppresses the precipitation of manganese from the inner surface of the chamber to prevent metal contamination of a substrate from the chamber.

Preferably, after the oxidizing gas is introduced into the chamber, the gas supply part stops gas supply into the chamber and the exhaust part stops gas exhaust from the chamber, whereby the oxidizing gas is sealed in the chamber for a predetermined waiting time period.

This reduces the consumption of the oxidizing gas.

Preferably, while the oxidizing gas is sealed in the chamber, the oxidizing gas sealed in the chamber is heated by light irradiation from the light irradiation part.

This shortens the processing time for the formation of the passive film.

Preferably, when an abnormality is detected while the oxidizing gas is sealed in the chamber, the gas supply part supplies nitrogen gas into the chamber to discharge the oxidizing gas after the exhausting part exhausts gas from the chamber to reduce pressure in the chamber.

This ensures safety in the event of abnormalities.

It is therefore an object of the present invention to prevent metal contamination of a substrate from a chamber.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of halogen lamps;

FIG. 8 is a block diagram showing a configuration of a controller;

FIG. 9 is a flow diagram showing a procedure of a passivation process for a chamber; and

FIG. 10 shows an example of a table.

### DESCRIPTION OF THE PREFERRED EMBODIMENTS

Preferred embodiments according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

### First Preferred Embodiment

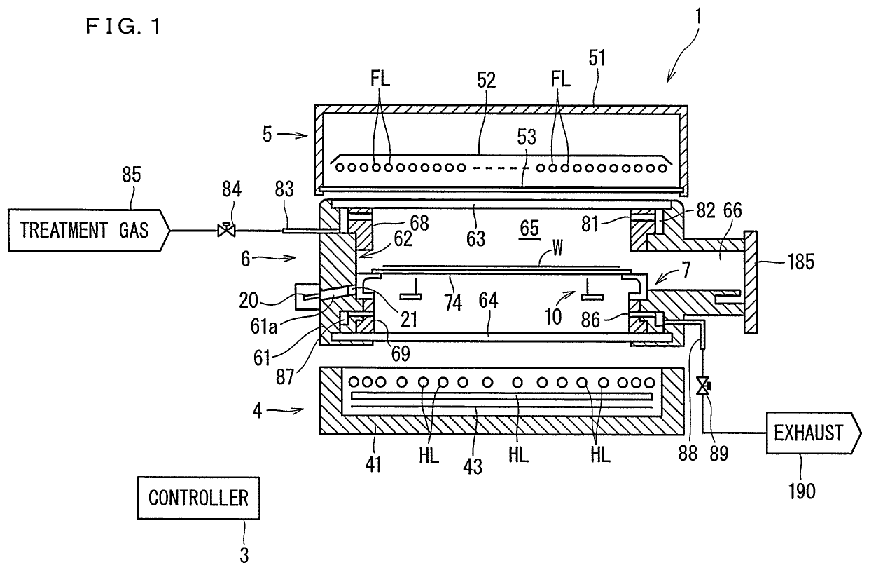

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material with high strength and high heat resistance, and are made of stainless steel (e.g., JIS (Japanese Industrial Standards) SUS 304 or SUS 430) in the present preferred embodiment.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a bored therein. A radiation thermometer 20 is mounted in a location of an outer wall surface of the chamber side portion 61 where the through hole 61a is provided. The through hole 61a is a cylindrical hole for directing infrared light emitted from a lower surface of a semiconductor wafer W held by a susceptor 74 to be described later therethrough to the radiation thermometer 20. The through hole 61a is inclined with respect to a horizontal direction so that a longitudinal axis (an axis extending in a direction in which the through hole 61a extends through the chamber side portion 61) of the through hole 61a intersects a main surface of the semiconductor wafer W held by the susceptor 74. A transparent window 21 made of barium fluoride material transparent to infrared light in a wavelength range measurable by the radiation thermometer 20 is mounted to an end portion of the through hole 61a which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A supply valve 84 is interposed in the gas supply pipe 83. When the supply valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases. The treatment gas supply source 85 is also able to supply ozone (O₃), oxygen (O₂), nitrogen oxides (NOₓ), or the like as an oxidizing gas. The nitrogen oxides include nitrogen monoxide (NO), nitrous oxide (N₂O), and nitrogen dioxide (NO₂). The treatment gas supply source 85 has an ozone generator not shown. An example of the process of supplying ozone as an oxidizing gas includes supplying oxygen from an oxygen cylinder to the ozone generator to generate ozone, and then feeding the ozone from the treatment gas supply source 85 to the gas supply pipe 83.

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. An exhaust valve 89 is interposed in the gas exhaust pipe 88. When the exhaust valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits.

The exhaust part 190 includes a vacuum pump. By operating the exhaust part 190 to exhaust the gas in the heat treatment space 65 without supplying gas through the gas supply opening 81, pressure in the chamber 6 is reduced to less than atmospheric pressure. The vacuum pump of the exhaust part 190 and the gas exhaust pipe 88 are connected to each other, for example, through three bypass lines having different diameters. The exhaust flow rate and exhaust speed from the chamber 6 are varied by opening any of the three bypass lines.

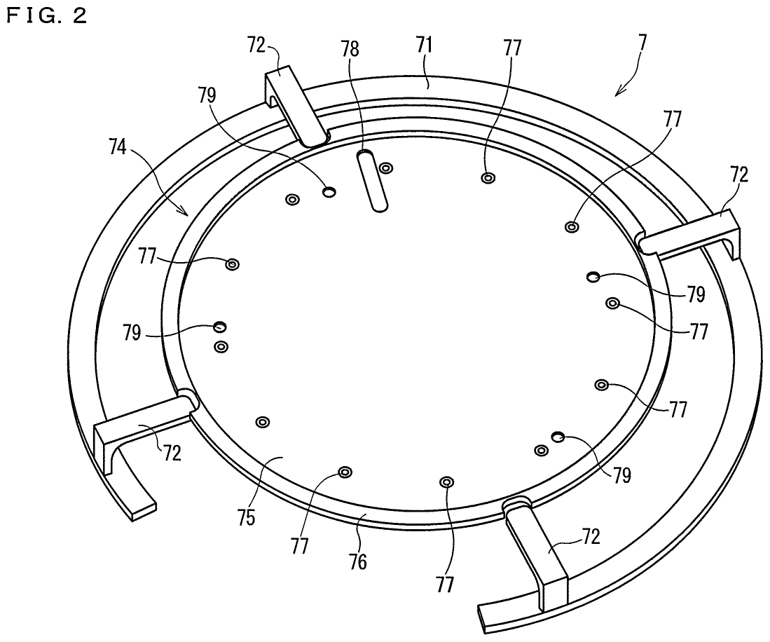

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

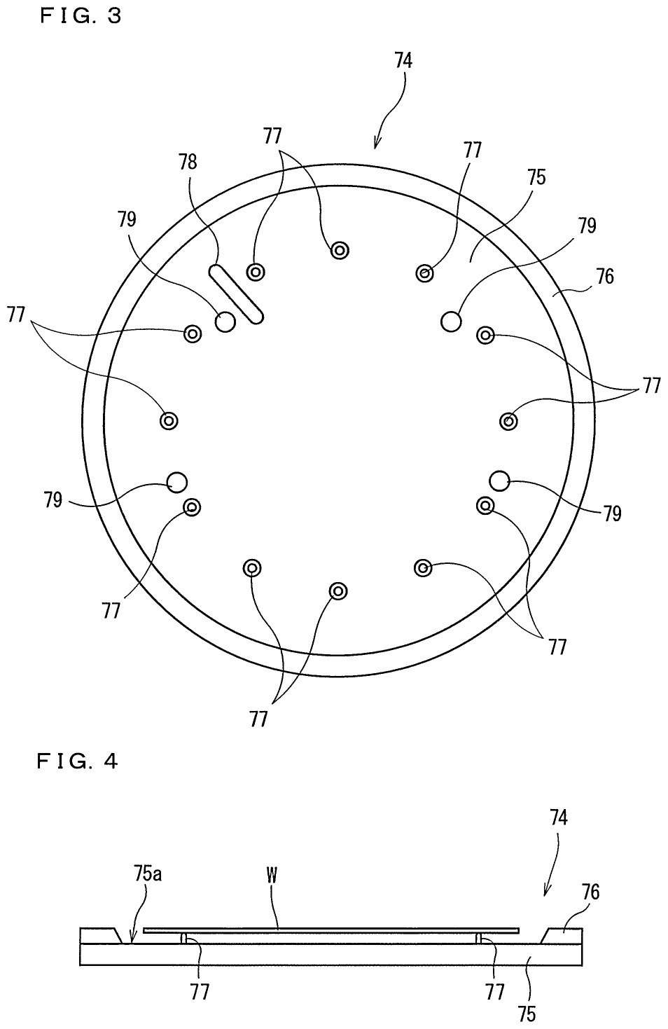

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the radiation thermometer 20 to receive radiation (infrared light) emitted from the lower surface of the semiconductor wafer W. Specifically, the radiation thermometer 20 receives the radiation emitted from the lower surface of the semiconductor wafer W through the opening 78 and the transparent window 21 mounted to the through hole 61a in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

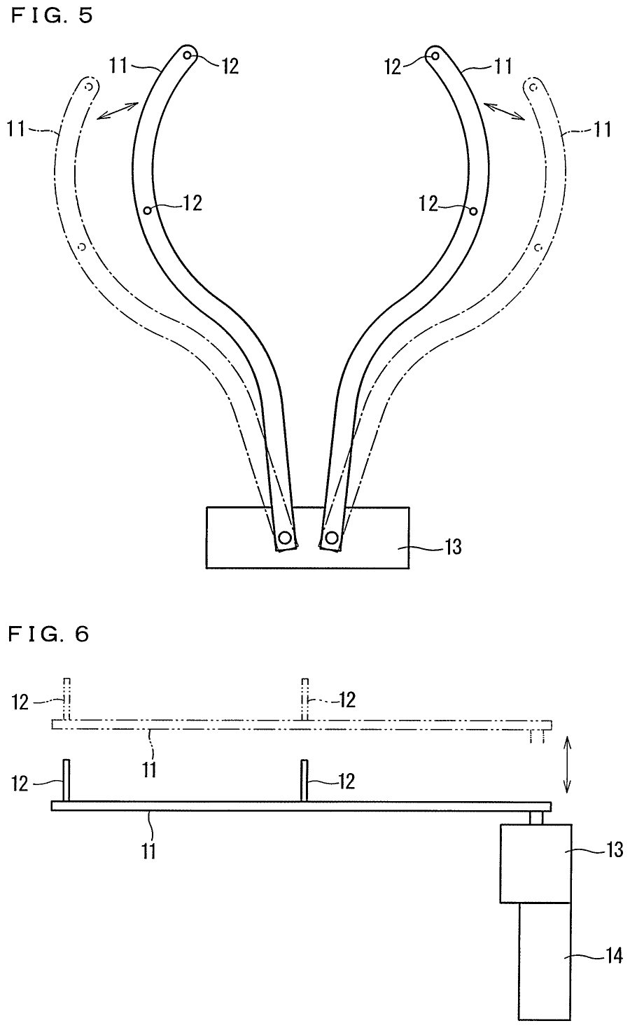

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 maybe of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 directs light from under the chamber 6 through the lower chamber window 64 toward the heat treatment space 65 to heat the semiconductor wafer W by means of the halogen lamps HL.

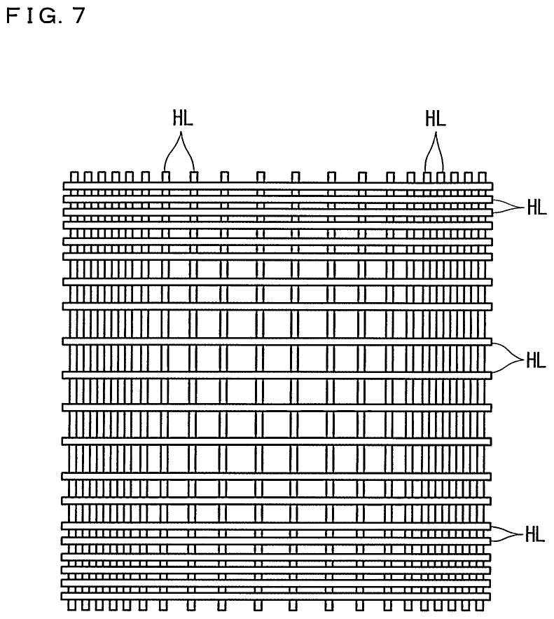

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

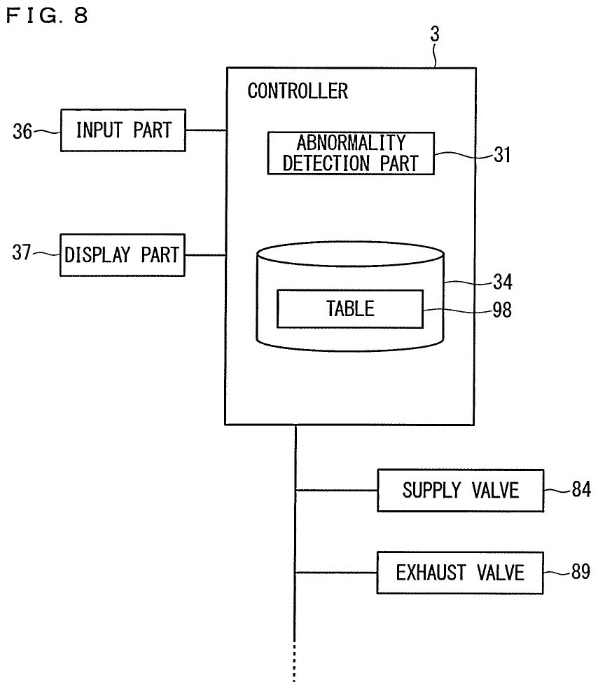

The controller 3 controls the aforementioned various operating mechanisms provided in the heat treatment apparatus 1. FIG. 8 is a block diagram showing a configuration of the controller 3. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part 34 (e.g., a magnetic disk or an SSD) for storing control software, data and the like thereon. The CPU in the controller 3 executes a predetermined processing program, whereby the processes in the heat treatment apparatus 1 proceed.

The controller 3 is electrically connected to elements including the supply valve 84, the exhaust valve 89, and the like. The controller 3 controls the operations of the supply valve 84, the exhaust valve 89, and the like.

The controller 3 includes an abnormality detection part 31. The abnormality detection part 31 is a functional processing part implemented by the CPU of the controller 3 executing a predetermined processing program. The abnormality detection part 31 detects abnormalities, based on detection signals from various sensors (not shown) provided in the heat treatment apparatus 1.

The controller 3 is also connected to a display part 37 and an input part 36. The display part 37 and the input part 36 function as a user interface for the heat treatment apparatus 1. The controller 3 causes various pieces of information to appear on the display part 37. An operator of the heat treatment apparatus 1 may input various commands and parameters from the input part 36 while viewing the information appearing on the display part 37. A keyboard and a mouse, for example, may be used as the input part 36. A liquid crystal display, for example, may be used as the display part 37. In the present preferred embodiment, a liquid crystal touch panel is used to function as both the display part 37 and the input part 36.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a processing operation in the heat treatment apparatus 1 will be described. A heat treatment operation for an ordinary semiconductor wafer (product wafer) W that becomes a product will be described first, and a passivation process for the chamber 6 of the heat treatment apparatus 1 will be thereafter described. A procedure for the treatment of the semiconductor wafer W which will be described below proceeds under the control of the controller 3 over the operating mechanisms of the heat treatment apparatus 1.

Prior to the treatment of the semiconductor wafer W, the supply valve 84 for supply of gas is opened, and the exhaust valve 89 for exhaust of gas is opened, so that the supply and exhaust of gas into and out of the chamber 6 start. When the supply valve 84 is opened, nitrogen gas is supplied through the gas supply opening 81 into the heat treatment space 65. When the exhaust valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

Subsequently, the gate valve 185 is opened to open the transport opening 66. A transport robot outside the heat treatment apparatus 1 transports a semiconductor wafer W to be treated through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface to be treated is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held in a horizontal attitude from below by the susceptor 74 of the holder 7 made of quartz, the 40 halogen lamps HL in the halogen heating part 4 turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving halogen light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W which is on the increase by the irradiation with light from the halogen lamps HL is measured by the radiation thermometer 20. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the radiation thermometer 20.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in the peripheral portion thereof where heat dissipation is liable to occur than in the central portion thereof. However, the halogen lamps HL in the halogen heating part 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL in the flash heating part 5 irradiate the front surface of the semiconductor wafer W held by the susceptor 74 with a flash of light at the point in time when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2 of 1000° C. or higher, and thereafter decreases rapidly.

After a predetermined time period has elapsed since the completion of the flash heating treatment, the halogen lamps HL turn off. This causes the temperature of the semiconductor wafer W to decrease rapidly from the preheating temperature T1. The radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed.

In the present preferred embodiment, the chamber 6 is made of stainless steel, and there is apprehension that manganese precipitates on an inner surface of the chamber 6 (more precisely, an inner wall surface of the chamber side portion 61) to adhere to the semiconductor wafer W, thereby causing metal contamination. A passive film as a native oxide film of chromium is formed on a surface of stainless steel. However, the passive film is damaged in some cases during the assembly of the chamber 6, and there is apprehension that metal contamination results from such damaged locations. To prevent this, a passivation process for the chamber 6 of the heat treatment apparatus 1 is performed in a manner to be described below in the present preferred embodiment.

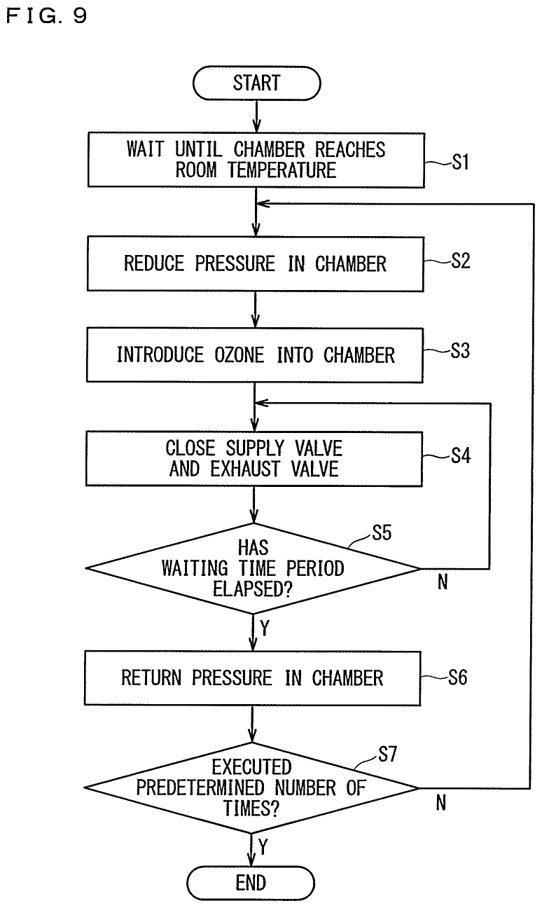

FIG. 9 is a flow diagram showing a procedure for the passivation process for the chamber 6. The passivation process for the chamber 6 maybe performed, for example, when the heat treatment apparatus 1 is assembled in a factory. In other words, the passivation process is one of the initial processes at the startup of the heat treatment apparatus 1.

The initial processes of the heat treatment apparatus 1 sometimes include adjusting the power balance of the halogen lamps HL and the flash lamps FL. At this time, the temperature of the chamber 6 is also increased because the halogen lamps HL and the flash lamps FL are turned on. When the temperature of the chamber 6 is increased, the heat treatment apparatus 1 waits until the temperature of the chamber 6 reaches room temperature (Step S1). The room temperature refers to the temperature of a clean room in which the heat treatment apparatus 1 is installed, and is 23° C., for example.

After the temperature of the chamber 6 reaches the room temperature, pressure in the chamber 6 is reduced (Step S2). Specifically, with the supply valve 84 closed and the exhaust valve 89 open, the controller 3 operates the exhaust part 190 to exhaust the gas in the chamber 6 through the gas exhaust pipe 88 to thereby reduce the pressure in the chamber 6 to less than atmospheric pressure.

After the pressure in the chamber 6 is reduced to a predetermined first pressure (e.g., 100 Pa), ozone (O₃) is introduced into the chamber 6 (Step S3). At this time, the exhaust valve 89 is kept open while the exhaust part 190 is operated, and the supply valve 84 is also opened. By opening the supply valve 84, ozone is supplied from the treatment gas supply source 85 into the chamber 6. The reduction in pressure in the chamber 6 prior to the introduction of ozone allows an ozone atmosphere of high purity to be rapidly formed in the chamber 6.

The supply of ozone into the chamber 6 increases the pressure in the chamber 6. When the pressure in the chamber 6 reaches a predetermined second pressure (e.g., 5000 Pa), the supply valve 84 and the exhaust valve 89 are closed (Step S4). Closing the supply valve 84 and the exhaust valve 89 stops the flow of gas into and out of the chamber 6, so that ozone is sealed in the chamber 6. It should be noted that the aforementioned second pressure is higher than the first pressure and lower than atmospheric pressure. Since ozone is sealed in the chamber 6 at a pressure less than atmospheric pressure, the pressure in the chamber 6 is a negative pressure relative to the outside atmosphere. This prevents hazardous ozone from leaking out of the chamber 6 with reliability.

In the first preferred embodiment, ozone is kept sealed in the chamber 6 at room temperature until a previously set waiting time period has elapsed (Step S5). Ozone has a extremely strong oxidizing power, and acts on the inner surface of the chamber 6 made of stainless steel to oxidize chromium, thereby forming an inert passive film on the inner surface. In other words, the passivation process proceeds. The passivation process caused by ozone repairs the damaged locations of the native oxide film described above to form a dense passive film on the inner surface of the chamber 6.

The waiting time period in the first preferred embodiment is not greater than the half-life of ozone. Ozone is a very unstable gas, and easily releases one oxygen atom (O) to become stable oxygen (O₂) (ozone decomposition). For this reason, ozone has a strong oxidizing power. The decomposition rate of ozone is highly temperature dependent. The higher the temperature is, the faster the decomposition rate is. Ozone decomposes gradually into oxygen even at room temperature, and the half-life of ozone at room temperature is 16 hours. In other words, half of the ozone is decomposed every 16 hours at room temperature. In the first preferred embodiment, ozone is sealed in the chamber 6 at room temperature, and the waiting time period in Step S5 is not greater than the half-life of ozone at room temperature (i.e., 16 hours). The waiting time period not greater than the half-life of ozone is previously set and stored, for example, in the storage part 34 of the controller 3.

After the aforementioned waiting time period has elapsed with ozone sealed in the chamber 6, the procedure proceeds from Step S5 to Step S6, in which the pressure in the chamber 6 is returned. At this time, the supply valve 84 is opened again to supply ozone or nitrogen from the treatment gas supply source 85 into the chamber 6. The supply of ozone or nitrogen into the chamber 6 returns the pressure in the chamber 6 to atmospheric pressure.

The series of processes from Step S2 to Step S6 complete one passivation process. The controller 3 determines whether the passivation process from Step S2 to Step S6 has been executed a previously set predetermined number of times or not (Step S7). If the number of times that the passivation process has been executed has not reached the set number of times, the passivation process from Step S2 to Step S6 is repeated until the set number of times is reached. In the first preferred embodiment, it is practical to repeat the passivation process two or three times because the maximum waiting time period with ozone sealed in the chamber 6 is 16 hours. Each time one cycle from Step S2 to Step S6 is completed, a metal check in which a dummy wafer is transported into the chamber 6 and subjected to a predetermined process may be executed, and the passivation process may be repeated until no manganese is detected from the dummy wafer.

In the first preferred embodiment, ozone is kept sealed in the chamber 6 at room temperature for the waiting time period that is not greater than the half-life of ozone. Ozone which has an extremely strong oxidizing power acts on the inner surface of the chamber 6 made of stainless steel, whereby chromium is oxidized to form the inert passive film on the inner surface. This inert passive film suppresses the precipitation of manganese from the chamber 6 made of stainless steel. This prevents metal contamination of the semiconductor wafer W from the chamber 6 even when the semiconductor wafer W is subjected to heating treatment in the chamber 6.

Also, ozone is sealed in the chamber 6 without supplying and exhausting gas to and from the chamber 6 for the waiting time period. This significantly reduces the consumption of ozone, as compared with a process in which ozone is kept flowing. In other words, a small amount of ozone is required to form the passive film on the inner surface of the chamber 6.

### Second Preferred Embodiment

Next, a second preferred embodiment of the present invention will be described. The second preferred embodiment is similar in configuration of the heat treatment apparatus 1 and in procedure for treatment of the semiconductor wafer W to the first preferred embodiment. Ozone is sealed in the chamber 6 at room temperature in the first preferred embodiment, whereas ozone is heated in the second preferred embodiment.

The second preferred embodiment is substantially similar in procedure for the passivation process to the first preferred embodiment (FIG. 9). In the second preferred embodiment, ozone is heated by the halogen lamps HL when the ozone is sealed in the chamber 6 in Steps S4 and S5. That is, the halogen lamps HL turn on, with ozone sealed in the chamber 6. In-chamber structures (structures in the chamber 6) including the susceptor 74, the chamber side portion 61, and the like are irradiated with light emitted from the halogen lamps HL, and the ozone in the chamber 6 is heated by heat conduction from the in-chamber structures increased in temperature by the irradiation. The temperature of the ozone atmosphere in the chamber 6 during the heating is in the range of 100° C. to 300° C. To improve the heating efficiency of ozone, the light irradiation from the halogen lamps HL may be performed, with a dummy wafer held by the susceptor 74. The dummy wafer is, for example, a bare wafer of silicon having the same shape as the semiconductor wafer W to be treated. The dummy wafer held by the susceptor 74 efficiently absorbs the light emitted from the halogen lamps HL to rapidly increase in temperature. This allows efficient heating of ozone from the dummy wafer.

Ozone, which is a very unstable gas, decomposes gradually into oxygen even at room temperature. The higher the temperature of ozone is, the faster the decomposition rate thereof is. The decomposition rate of ozone becomes pronouncedly faster when the temperature of ozone is 100° C. or higher, and the half-life of the decomposition reaction is only several seconds at a temperature of 200° C. or higher.

Thus, the waiting time period for which ozone is kept sealed in the chamber 6 is pronouncedly shortened in the second preferred embodiment. The maximum waiting time period with ozone kept sealed in the chamber 6 is 16 hours in the first preferred embodiment, whereas the waiting time period can be as short as several seconds in the second preferred embodiment.

The second preferred embodiment, in which the inert passive film is formed on the inner surface of the chamber 6, also suppresses the precipitation of manganese to prevent metal contamination of the semiconductor wafer W from the chamber 6. In addition, the second preferred embodiment shortens the waiting time period for which ozone is kept sealed because the ozone sealed in the chamber 6 is heated. This allows the time required to form the passive film on the inner surface of the chamber 6 to be shorter than in the first preferred embodiment. However, there are cases in which the consumption of ozone in the second preferred embodiment is greater than in the first preferred embodiment.

In the second preferred embodiment, the ozone sealed in the chamber 6 maybe heated by flash irradiation from the flash lamps FL in place of or in in addition to the halogen lamps HL.

### Third Preferred Embodiment

Next, a third preferred embodiment of the present invention will be described. The third preferred embodiment is similar in configuration of the heat treatment apparatus 1 and in procedure for treatment of the semiconductor wafer W to the first preferred embodiment.

The third preferred embodiment is substantially similar in procedure for the passivation process to the first and second preferred embodiments. That is, ozone is kept sealed in the chamber 6 for the predetermined waiting time period. The sealed ozone may be at room temperature as in the first preferred embodiment or be heated as in the second preferred embodiment.

In the third preferred embodiment, the waiting time period is determined based on temperature in the chamber 6, pressure in the chamber 6, and ozone concentration. Specifically, a table 98 in which the temperature in the chamber 6, the pressure in the chamber 6, and the ozone concentration are associated with the waiting time period is previously created and stored, for example, in the storage part 34 of the controller 3 (FIG. 8).

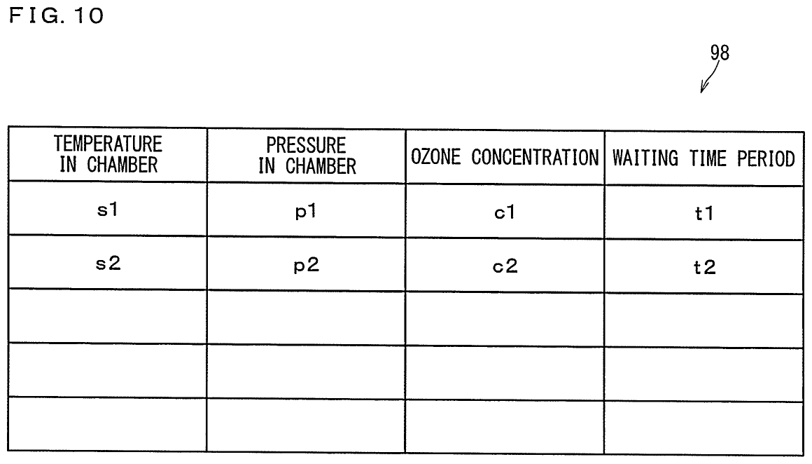

FIG. 10 shows an example of the table 98. As shown in FIG. 10, the temperature in the chamber 6, the pressure in the chamber 6, and the ozone concentration are registered in association with the waiting time period in the table 98. The temperature in the chamber 6, the pressure in the chamber 6, and the ozone concentration determine the degree of ozone decomposition, which in turn determines the appropriate waiting time period. As an example, the waiting time period for which ozone is sealed in the chamber 6 is t1, when the temperature in the chamber 6 is s1, the pressure in the chamber 6 is p1, and the ozone concentration is c1. Such a table 98 may be previously created by experiment or simulation and stored in the storage part 34.

In the third preferred embodiment, the controller 3 determines the waiting time period from the temperature in the chamber 6, the pressure in the chamber 6, and the ozone concentration, based on the table 98. The ozone concentration is a fixed value obtained when the ozone generator of the treatment gas supply source 85 generates ozone. The pressure in the chamber 6 is also a constant value obtained when the supply valve 84 and the exhaust valve 89 are closed if there is no gas leakage from the chamber 6. The temperature in the chamber 6 is room temperature in the first preferred embodiment, and is, for example, the value of the temperature of the dummy wafer held by the susceptor 74 which is measured by the radiation thermometer 20 plus a predetermined offset in the second preferred embodiment. The controller 3 determines the waiting time period, based on the table 98, and maintains the ozone sealed in the chamber 6 for the waiting time period.

The third preferred embodiment, in which the inert passive film is formed on the inner surface of the chamber 6, also suppresses the precipitation of manganese to prevent metal contamination of the semiconductor wafer W from the chamber 6. In addition, the third preferred embodiment is capable of optimizing the waiting time period for which ozone is kept sealed in the chamber 6 to restrain the time for the passivation process from becoming unnecessarily prolonged.

### Fourth Preferred Embodiment

Next, a fourth preferred embodiment of the present invention will be described. The fourth preferred embodiment is similar in configuration of the heat treatment apparatus 1 and in procedure for treatment of the semiconductor wafer W to the first preferred embodiment.

The fourth preferred embodiment is substantially similar in procedure for the passivation process to the first to third preferred embodiments. That is, ozone is kept sealed in the chamber 6 for the predetermined waiting time period. The sealed ozone may be at room temperature as in the first preferred embodiment or be heated as in the second preferred embodiment.

In the fourth preferred embodiment, when some abnormality is detected while ozone is sealed in the chamber 6, nitrogen gas is supplied into the chamber 6 to discharge the ozone after the pressure in the chamber 6 is reduced. When the passivation process proceeds while ozone is sealed in the chamber 6, there are cases in which the abnormality detection part 31 (FIG. 8) detects some abnormality. For example, when an abnormality such that light irradiation from the halogen lamps HL for heating of the sealed ozone becomes too strong and causes a fuse provided in the chamber 6 to blow occurs, the abnormality detection part 31 detects the abnormality.

When the abnormality detection part 31 detects an abnormality while ozone is sealed in the chamber 6, the controller 3 opens the exhaust valve 89 and operates the exhaust part 190 to exhaust the ozone in the chamber 6 through the gas exhaust pipe 88, thereby reducing the pressure in the chamber 6. Thereafter, the controller 3 opens the supply valve 84 to supply nitrogen from the treatment gas supply source 85 into the chamber 6. This results in the rapid discharge of ozone from the chamber 6.

The fourth preferred embodiment, in which the inert passive film is formed on the inner surface of the chamber 6, also suppresses the precipitation of manganese to prevent metal contamination of the semiconductor wafer W from the chamber 6. In addition, the fourth preferred embodiment is capable of rapidly discharging ozone from the chamber 6 even when some abnormality occurs while the ozone is sealed in the chamber 6.

This provides a high degree of safety.

### Modifications

While the preferred embodiments according to the present invention have been described hereinabove, various modifications of the present invention in addition to those described above may be made without departing from the scope and spirit of the invention. For example, although ozone is sealed in the chamber 6 in the aforementioned preferred embodiments, oxygen, nitrogen oxides, or the like may be sealed in the chamber 6 in place of ozone. In other words, it is only necessary that the heat treatment apparatus 1 is configured to seal an oxidizing gas in the chamber 6. By sealing the oxidizing gas having an oxidizing power in the chamber 6, chromium is oxidized to form the inert passive film on the inner surface of the chamber 6. However, ozone is preferable for the formation of the passive film because of its extremely strong oxidizing power among oxidizing gases.

Although the 30 flash lamps FL are provided in the flash heating part 5 in the aforementioned preferred embodiments, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiments, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been described in detail, the foregoing description is in all aspects illustrative and not restrictive. It is understood that numerous other modifications and variations can be devised without departing from the scope of the invention.

What is claimed is:

1. A method of passivation for forming a passive film on an inner surface of a chamber of a heat treatment apparatus for heat-treating a substrate, said method comprising the steps of:
(a) introducing an oxidizing gas into a chamber containing stainless steel; and
(b) forming a passive film on an inner surface of said chamber by means of said oxidizing gas.

2. The method according to claim 1, further comprising the step of
(c) stopping gas supply into and gas exhaust from said chamber to seal said oxidizing gas in said chamber for a predetermined waiting time period after introducing said oxidizing gas into said chamber.

3. The method according to claim 2,
wherein said waiting time period is not greater than the half-life of said oxidizing gas.

4. The method according to claim 2,
wherein a heat source heats said oxidizing gas sealed in said chamber during the execution of said step (c).

5. The method according to claim 4,
wherein said heat source heats an atmosphere in said chamber to between 100° C. and 300° C.

6. The method according to claim 4,
wherein said waiting time period is determined based on temperature in said chamber, pressure in said chamber, and the concentration of said oxidizing gas.

7. The method according to claim 2,
wherein, when an abnormality is detected during the execution of said step (c), nitrogen gas is supplied into said chamber to discharge said oxidizing gas after pressure in said chamber is reduced.

8. The method according to claim 2,
wherein pressure in said chamber is reduced before said step (a).

9. The method according to claim 1,
wherein said oxidizing gas is ozone.

10. The method according to claim 9,
wherein said heat treatment apparatus irradiates a substrate with light from a continuous lighting lamp and a flash lamp to heat said substrate.

11. A heat treatment apparatus for heating a substrate by irradiating the substrate with light, comprising:
a chamber containing stainless steel;
a gas supply part for supplying an oxidizing gas into said chamber;
an exhaust part for exhausting gas from said chamber; and
a light irradiation part for irradiating the interior of said chamber with light,
wherein a passive film is formed on an inner surface of said chamber by means of said oxidizing gas supplied by said gas supply part.

12. The heat treatment apparatus according to claim 11,
wherein, after said oxidizing gas is introduced into said chamber, said gas supply part stops gas supply into said chamber and said exhaust part stops gas exhaust from said chamber, whereby said oxidizing gas is sealed in said chamber for a predetermined waiting time period.

13. The heat treatment apparatus according to claim 12,
wherein said waiting time period is not greater than the half-life of said oxidizing gas.

14. The heat treatment apparatus according to claim 12,
wherein, while said oxidizing gas is sealed in said chamber, said oxidizing gas sealed in said chamber is heated by light irradiation from said light irradiation part.

15. The heat treatment apparatus according to claim 14,
wherein an atmosphere in said chamber is heated to between 100° C. and 300° C. by the light irradiation from said light irradiation part.

16. The heat treatment apparatus according to claim 14, further comprising
a storage part for holding a table in which temperature in said chamber, pressure in said chamber, and the concentration of said oxidizing gas are associated with said waiting time period,
wherein said waiting time period is determined based on said table.

17. The heat treatment apparatus according to claim 12,
wherein, when an abnormality is detected while said oxidizing gas is sealed in said chamber, said gas supply part supplies nitrogen gas into said chamber to discharge said oxidizing gas after said exhausting part exhausts gas from said chamber to reduce pressure in said chamber.

18. The heat treatment apparatus according to claim 12,
wherein said exhaust part exhausts gas from said chamber to reduce pressure in said chamber before said oxidizing gas is introduced into said chamber.

19. The heat treatment apparatus according to claim 11,
wherein said oxidizing gas is ozone.

20. The heat treatment apparatus according to claim 19,
wherein said light irradiation part includes a continuous lighting lamp and a flash lamp.
